(19) United States
(12) Patent Application Publication
(10) Pub. No.: US 2018/0286806 A1
(43) Pub. Date: Oct. 4, 2018

(54) SEMICONDUCTOR DEVICE HAVING MULTILAYER INTERCONNECTION STRUCTURE AND METHOD OF MANUFACTURING THE SAME

(71) Applicant: SK hynix Inc., Icheon (KR)

(72) Inventors: In Hoe KIM, Seoul (KR); Young Min NA, Hanam (KR); Gwang Won LEE, Suwon (KR); Jong Young CHO, Hanam (KR)

(21) Appl. No.: 15/824,968

(22) Filed: Nov. 28, 2017

(30) Foreign Application Priority Data
Mar. 31, 2017 (KR) 10-2017-0042070

(51) Int. Cl. H01L 23/522; H01L 23/532; H01L 21/321; H01L 21/768; H01L 21/285; H01L 23/485

(52) U.S. Cl. CPC H01L 23/5226; H01L 23/53223; H01L 21/3212; H01L 21/76846; H01L 23/5329; H01L 21/7685; H01L 21/76879; H01L 23/485; H01L 23/53266; H01L 21/2855

(57) ABSTRACT

A method of manufacturing a semiconductor device includes forming a stacked structure including at least one interconnection pattern layer and at least one contact plug on over a substrate, forming an interlayer insulation material layer over an uppermost interconnection pattern layer or an uppermost contact plug of the stacked structure, patterning the interlayer insulation layer to form an interlayer insulation layer including one or more openings that expose the uppermost interconnection pattern layer or the uppermost contact plug, forming a metal nitride thin film along a surface of a resulting structure of the interlayer insulation layer, forming a metal thin film over the metal nitride thin film by filling at least the remaining portions of the one or more openings after the metal nitride thin film is formed, and planarizing the metal thin film and the metal nitride thin film using chemical mechanical polishing.

### CROSS-REFERENCE TO RELATED APPLICATION

The present application claims priority under 35 U.S.C 119(a) to Korean Patent Application No. 10-2017-0042070, filed on Mar. 31, 2017, which is incorporated by reference herein its entirety.

### BACKGROUND

### 1. Technical Field

Various embodiments of the present disclosure generally relate to a semiconductor device and, more particularly, to a semiconductor device having a multilayer interconnection structure and a method of manufacturing the same.

### 2. Related Art

Generally, an interconnection pattern of a semiconductor device can be formed by forming a conductive film and patterning the conductive film to form the interconnection pattern. Recently, in order to reduce the resistance of the interconnection pattern, a metal has been used as an interconnection material, and a damascene process including a chemical mechanical polishing (CMP) has been used to form the metal interconnection pattern.

Meanwhile, in recent years, as the pattern size of a semiconductor device decreases and the pattern density of a semiconductor device increases, research has been conducted to improve the reliability of CMP for planarizing a metal thin film. More specifically, a technique for effectively grinding a metal thin film using polishing slurry and a polishing pad, and a technique for effectively controlling a chemical reaction between the polishing slurry and the metal thin film have been studied.

### SUMMARY

There is disclosed a method of manufacturing a semiconductor device having a multilayer interconnection structure according to an aspect of the present disclosure. In the method, a stacked structure including at least one interconnection pattern layer and at least one contact plug is formed over a substrate. The at least one interconnection pattern layer includes an uppermost interconnection layer, and the at least one contact plug includes an uppermost contact plug. An interlayer insulation material layer is formed over the uppermost interconnection pattern layer or the uppermost contact plug of the stacked structure. The interlayer insulation material layer is patterned to form an interlayer insulation layer including one or more openings. The one or more openings expose the uppermost interconnection pattern layer or the uppermost contact plug. A metal nitride thin film is formed along a surface of a resulting structure including the one or more openings of the interlayer insulation layer. A metal thin film is formed over the metal nitride thin film by filling at least the remaining portions of the one or more openings after the metal nitride thin film is formed. The metal thin film and the metal nitride thin film are planarized using chemical mechanical polishing. The metal thin film and the metal nitride thin film include the same metal element, and the at least one interconnection pattern layer includes a conductive material having resistivity lower than that of the metal thin film.

There is disclosed a method of manufacturing a semiconductor device having a multilayer interconnection structure according to another aspect of the present disclosure. In the method, a stacked structure including at least one interconnection pattern layer and at least one contact plug is formed over a substrate. the at least one interconnection pattern layer including an uppermost interconnection layer, the at least one contact plug including an uppermost contact plug. An interlayer insulation material layer is formed over the uppermost interconnection pattern layer or the uppermost contact plug of the stacked structure. The interlayer insulation material layer is patterned to form an interlayer insulation layer including one or more openings. The one or more openings expose the uppermost interconnection pattern layer or the uppermost contact plug. A metal nitride thin film is formed along a surface of a resulting structure including the one or more openings of the interlayer insulation layer. A metal thin film is formed over the metal nitride thin film by filling at least the remaining portions of the one or more openings after the metal nitride thin film is formed. The metal thin film and the metal nitride thin film are planarized using chemical mechanical polishing. The at least one interconnection pattern layer includes a conductive material having resistivity lower than that of the metal thin film. The metal nitride thin film is formed using a metal organic material as a metal source material.

There is disclosed a semiconductor device having a multilayer interconnection structure according to another aspect of the present disclosure. The semiconductor device includes a stacked structure disposed over a substrate and including at least one interconnection pattern layer and at least one contact plug. The at least one interconnection pattern layer includes an uppermost interconnection layer, and the at least one contact plug includes an uppermost contact plug. The semiconductor device also includes an interlayer insulation layer disposed over the uppermost interconnection pattern layer or the uppermost contact plug of the stacked structure. The semiconductor device further includes a conductive plug disposed in the interlayer insulation layer and connected to the uppermost interconnection pattern layer or the uppermost contact plug. Here, the conductive plug includes a metal nitride barrier layer contacting the interlayer insulation layer and the uppermost interconnection pattern layer or contacting the interlayer insulation layer and the uppermost contact plug, and a metal plug disposed on the metal nitride barrier layer. The at least one interconnection pattern layer includes a conductive material having resistivity lower than that of the metal plug.

### BRIEF DESCRIPTION OF THE DRAWINGS

FIGS. 1A and 1B are cross-sectional views illustrating a semiconductor device having a multilayer interconnection structure according to a first embodiment of the present disclosure.

FIGS. 2A and 2B are cross-sectional views illustrating a semiconductor device having a multilayer interconnection structure according to a second embodiment of the present disclosure.

FIG. 3A is a cross-sectional image of a semiconductor device having a multilayer interconnection structure according to a comparative example. FIG. 3B illustrates a cross-sectional view of the semiconductor device according to the comparative example.

FIG. 4 is a flow chart illustrating a method of manufacturing a semiconductor device having a multilayer interconnection structure according to an embodiment of the present disclosure.

FIGS. 5A to 9B illustrate a method of manufacturing a semiconductor device having a multilayer interconnection structure according to an embodiment of the present disclosure. FIGS. 5A, 6A, 7A, 8A, and 9A are cross-sectional views of the semiconductor device on an X-Z plane, and FIGS. 5B, 6B, 7B, 8B, and 9B are cross-sectional views of the semiconductor device on a Y-Z plane.

FIGS. 10A to 12B illustrate a method of manufacturing a semiconductor device having a multilayer interconnection structure according to another embodiment of the present disclosure. FIGS. 10A, 11A, and 12A are cross-sectional views of the semiconductor device on an X-Z plane, and FIGS. 10B, 11B, and 12B are cross-sectional views of the semiconductor device on a Y-Z plane.

FIGS. 13A and 13B are graphs each illustrating a potential and a current density of an electrode reaction for a material under different process conditions of a chemical mechanical polishing, according to an embodiment of the present disclosure.

### DETAILED DESCRIPTION

Various embodiments will now be described hereinafter with reference to the accompanying drawings. In the drawings, the dimensions of layers and regions may be exaggerated for clarity of illustration. The drawings are described with respect to an observer's viewpoint. If an element is referred to be located on another element, it may be understood that the element is directly located on the other element, or an additional element may be interposed between the element and the other element. The same reference numerals refer to the same elements throughout the specification.

In addition, expression of a singular form of a word should be understood to include the plural forms of the word unless clearly used otherwise in the context. It will be understood that the terms “comprise” or “have” are intended to specify the presence of a feature, a number, a step, an operation, an element, a part, or combinations thereof, but not used to preclude the presence or possibility of addition one or more other features, numbers, steps, operations, components, parts, or combinations thereof.

Further, in performing a method or a manufacturing method, each process constituting the method can take place differently from the stipulated order unless a specific sequence is described explicitly in the context. In other words, each process may be performed in the same manner as stated order, may be performed substantially at the same time, or may be performed in a reverse order.

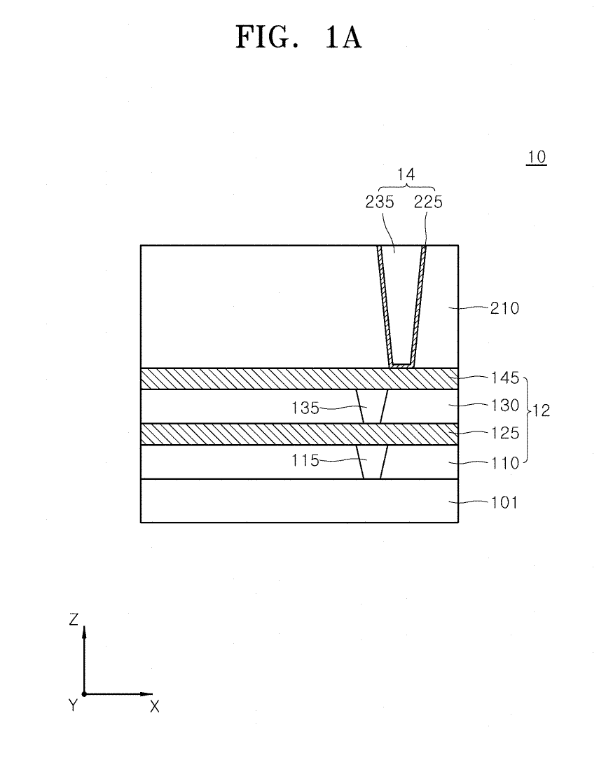

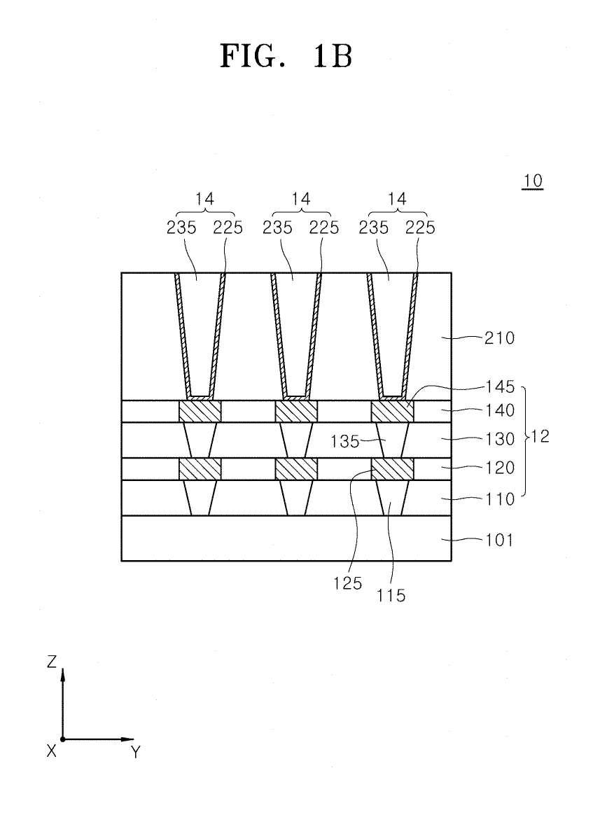

FIGS. 1A and 1B are cross-sectional views schematically illustrating a semiconductor device 10 having a multilayer interconnection structure according to a first embodiment of the present disclosure. Specifically, FIG. 1A is a cross-sectional view of the semiconductor device 10 on an X-Z plane of an X-axis and a Z-axis, and FIG. 1B is a cross-sectional view of the semiconductor device 10 on a Y-Z plane of a Y-axis and the Z-axis.

Referring to FIGS. 1A and 1B, the semiconductor device 10 may include a stacked structure 12 disposed on a substrate 101. The stacked structure 12 may include first and second interconnection pattern layers 125 and 145, first, second, third, and fourth insulation layers 110, 120, 130, and 140, and first and second contact plugs 115 and 135.

The semiconductor device 10 may further include a conductive plug 14 disposed on the second interconnection pattern layer 145. The conductive plug 14 may be disposed in an interlayer insulation layer 210 and may be electrically connected to the second interconnection pattern layer 145. The conductive plug 14 may include a metal nitride barrier layer 225 and a metal plug 235.

The substrate 101 may, for example, be a semiconductor substrate. Specifically, the substrate 101 may, for example, be a silicon (Si) substrate, a gallium arsenide (GaAs) substrate, an indium phosphide (InP) substrate, a germanium (Ge) substrate, silicon germanium (SiGe) substrate, or a silicon-on-insulator (SOI) substrate. The substrate 101 may be doped with n-type or p-type impurities. The substrate 101 may have one or more wells, each of which is at least partially doped with n-type or p-type impurities.

The first contact plug 115 may be disposed on the substrate 101. The first contact plug 115 may be disposed in the first insulation layer 110. The first contact plug 115 may connect the substrate 101 to the first interconnection pattern layer 125. The first insulation layer 110 may, for example, include an oxide material having a low dielectric constant, such as silicon oxide.

The first contact plug 115 may include a metal or metal nitride. The first contact plug 115 may include, for example, tungsten (W), tungsten nitride, titanium nitride, or the like. In some embodiments, the first contact plug 115 may include a conductive material having lower resistivity than that of the metal plug 235. As an example, the first contact plug 115 may include copper (Cu), cobalt (Co), or platinum (Pt) when the metal plug 235 includes tungsten (W).

In some embodiments, the first contact plug 115 may include a diffusion barrier layer contacting the first insulation layer 110 and the substrate 101. The diffusion barrier layer may include, for example, tungsten nitride or titanium nitride.

Referring to FIGS. 1A and 1B, the first interconnection pattern layer 125 may be disposed on the first insulation layer 110 and the first contact plug 115. The first interconnection pattern layer 125 may be electrically connected to the substrate 101 via the first contact plug 115. In an embodiment, the first interconnection pattern layer 125 may include a conductive material having resistivity lower than that of the metal plug 235. As an example, when the metal plug 235 includes tungsten (W), the first interconnection pattern layer 125 may include copper (Cu), cobalt (Co), or platinum (Pt). As illustrated in FIG. 1B, the first interconnection pattern layer 125 may be electrically insulated from neighboring first interconnection pattern layers 125 by the second insulation layer 120. The second insulation layer 120 may, for example, include an oxide material having a low dielectric constant, such as silicon oxide.

The third insulation layer 130 may be disposed on the first interconnection pattern layer 125 and the second insulation layer 120. The second contact plug 135 may be disposed in the third insulation layer 130. The second contact plug 135 may electrically connect the first interconnection pattern layer 125 to the second interconnection pattern layer 145. A configuration of the third insulation layer 130 and the second contact plug 135 may be substantially the same as a configuration of the first insulation layer 110 and the first contact plug 115.

The second interconnection pattern layer 145 may be disposed on the second contact plug 135. The second interconnection pattern layer 145 may be electrically connected to the second contact plug 135. As illustrated in FIG. 1B, the second interconnection pattern layer 145 may be electrically insulated from neighboring second interconnection pattern layers 145 by the fourth insulation layer 140. The fourth insulation layer 140 may, for example, include an oxide material having a low dielectric constant, such as silicon oxide.

Although the stacked structure 12 according to the embodiment shown in FIGS. 1A and 1B includes two interconnection pattern layers 125 and 145 and the first and second contact plugs 115 and 135 that are alternately stacked in a z-axis direction, but embodiments of the present disclosure are not limited thereto. According to an embodiment, the stacked structure 12 may include at least one interconnection pattern layer and at least one contact plug.

The interlayer insulation layer 210 may be disposed over the stacked structure 12, and the conductive plug 14 may be disposed in the interlayer insulation layer 210. The conductive plug 14 may be electrically connected to the substrate 101 through the first and second interconnection pattern layers 125 and 145 and the first and second contact plugs 115 and 135. As described above, the conductive plug 14 may include the metal nitride barrier layer 225 and the metal plug 235. The metal nitride barrier layer 225 may contact the interlayer insulation layer 210 and the second interconnection pattern layer 145. The metal plug 235 may be disposed on the metal nitride barrier layer 225.

In an embodiment, the metal plug 235 and the metal nitride barrier layer 225 may include the same metal element. As an example, when the metal plug 235 includes tungsten (W), the metal nitride barrier layer 225 may include tungsten nitride.

In an embodiment, the metal nitride barrier layer 225 may have an amorphous phase. As an example, when the metal plug 235 includes tungsten (W), the metal nitride barrier layer 225 may include titanium nitride having an amorphous phase.

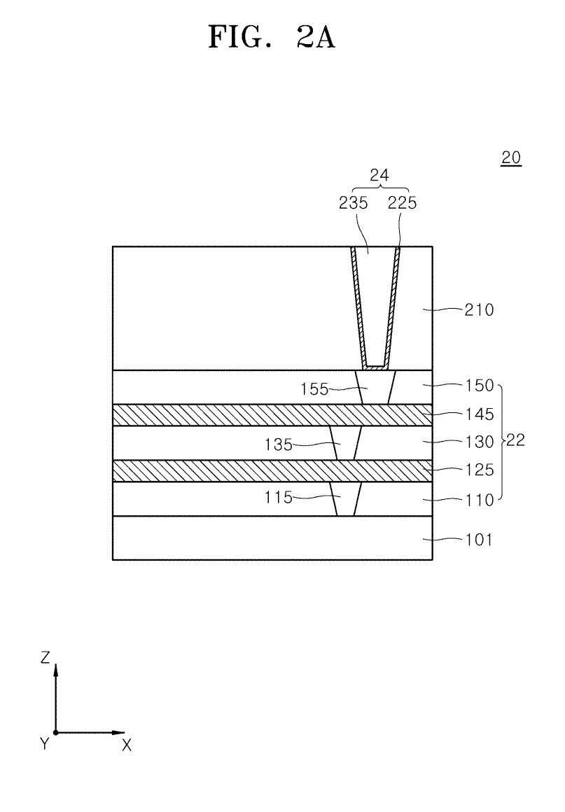

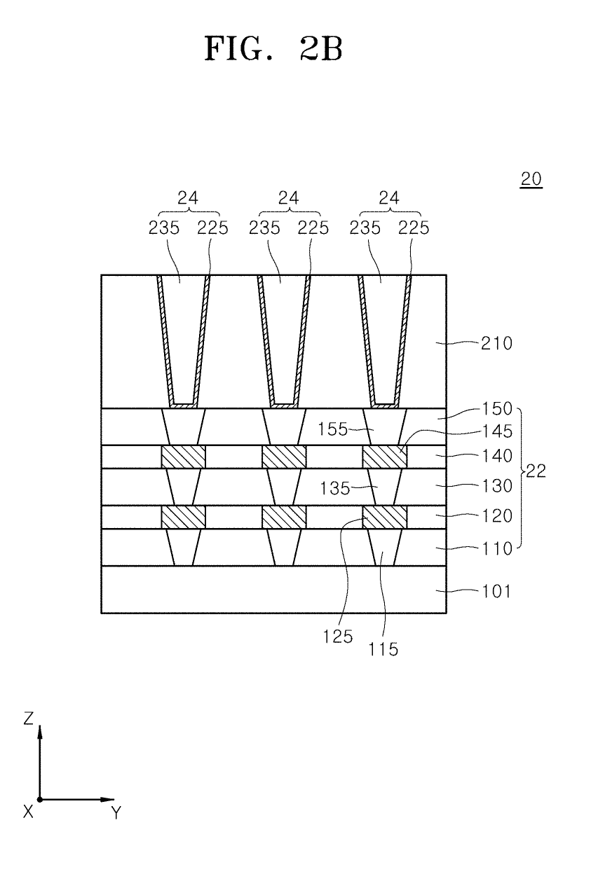

FIGS. 2A and 2B are cross-sectional views schematically illustrating a semiconductor device 20 having a multilayer interconnection structure according to a second embodiment of the present disclosure. Specifically, FIG. 2A is a cross-sectional view of the semiconductor device 20 on an X-Z plane of an X-axis and a Z-axis, and FIG. 2B is a cross-sectional view of the semiconductor device 20 on a Y-Z plane of a Y-axis and the Z-axis.

Referring to FIGS. 2A and 2B, the semiconductor device 20 may include a stacked structure 22 and a conductive plug 24 disposed over a substrate 101. The semiconductor device 20 may have a configuration that is substantially the same as that of the semiconductor device 10 described above with reference to FIGS. 1A and 1B, except in that the stacked structure 22 of the semiconductor device 20 in FIGS. 2A and 2B additionally includes a third contact plug 155 and a fifth insulation layer 150.

The third contact plug 155 may be disposed on a second interconnection pattern layer 145 to electrically connect the second interconnection pattern layer 145 to the conductive plug 24. A configuration of the third contact plug 155 and the fifth insulation layer 150 may be substantially the same as that of the first contact plug 115 and the first insulation layer 110 and that of the second contact plug 135 and the third insulation layer 130, when seen from the Y-Z plane of FIG. 2B.

The fifth insulation layer 150 may include the same material as those of first to fourth insulation layers 110, 120, 130, and 140. As an example, the fifth insulation layer 150 may include an oxide material having a low dielectric constant, such as silicon oxide.

Referring to FIGS. 2A and 2B, the conductive plug 24 may be disposed on the third contact plug 155. The conductive plug 24 may include a metal nitride barrier layer 225 and a metal plug 235. The conductive plug 24 may be disposed in an interlayer insulation layer 210.

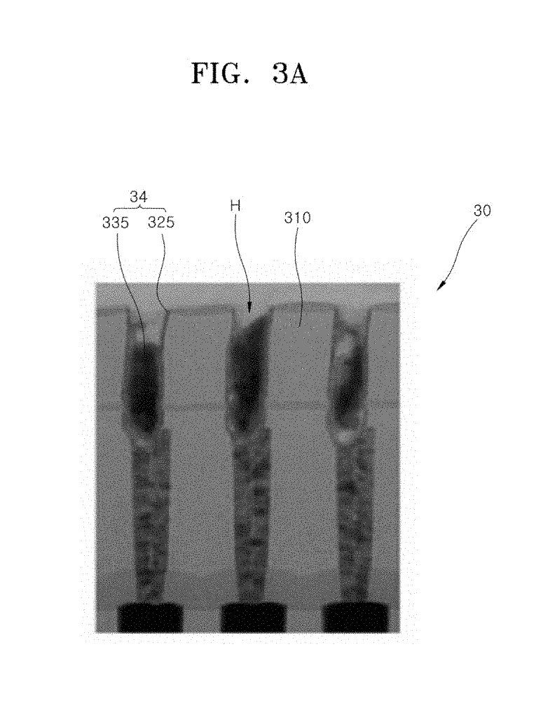

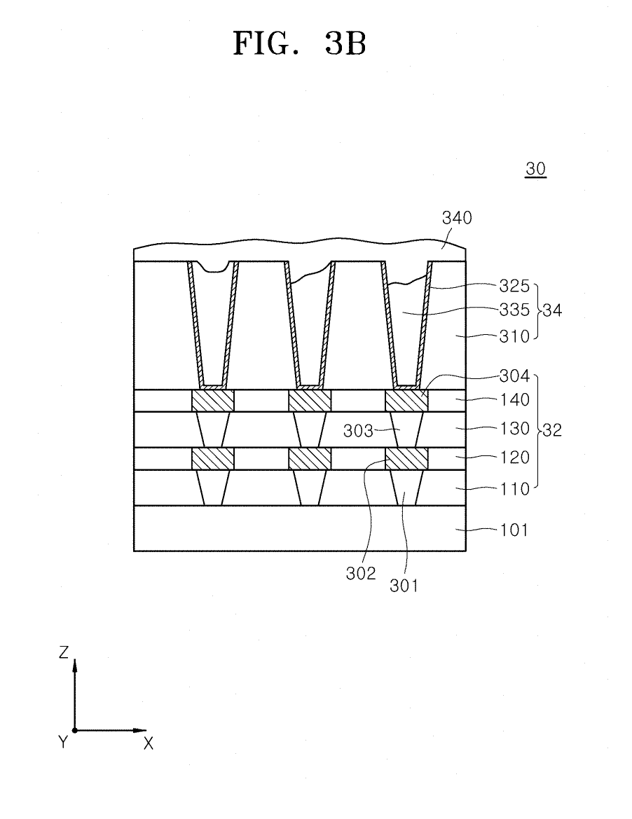

FIG. 3A is a cross-sectional image of a semiconductor device 30 having a multilayer interconnection structure, according to a comparative example. FIG. 3B illustrates a cross-sectional view of the semiconductor device 30 according to the comparative example. The semiconductor device 30 illustrated in FIGS. 3A and 3B can be relatively weak in an aspect of the structural stability of a conductive plug 34, as compared with the semiconductor devices 10 and 20 according to the first and second embodiments described above. The conductive plug 34 may, for example, include a titanium nitride barrier layer 325 and a tungsten plug 335.

Referring to FIG. 3A, it can be observed that an upper portion of the tungsten plug 335 adjacent to an upper portion of an interlayer insulation layer 310 was lost and therefore a hole H was formed. The upper portion of the tungsten plug 335 may be lost, for example, in a process of filling a titanium nitride thin film and a tungsten thin film in openings formed in the interlayer insulation layer 310 and then planarizing the titanium nitride thin film and the tungsten thin film using a chemical mechanical polishing.

Hereinafter, with reference to FIG. 3B, the phenomenon in which the upper portion of the tungsten plug 335 is lost when the chemical mechanical polishing is performed will be described in more detail. Such disappearance of the upper portion of the tungsten plug 335 may result from a galvanic corrosion phenomenon.

As illustrated in FIG. 3B, when the chemical mechanical polishing is performed on the titanium nitride thin film and the tungsten thin film, a solution 340 containing polishing slurry may be provided over a substrate 101 over which the titanium nitride thin film and the tungsten thin film are formed. When the titanium nitride barrier layer 325 and the tungsten plug 335 are formed, the solution 340 containing the polishing slurry may contact the titanium nitride barrier layer 325 and the tungsten plug 335. At this time, galvanic corrosion may occur when the solution 340 functions as an electrolyte solution and the titanium nitride barrier layer 324 and the tungsten plug 335 function as anode and cathode electrodes, respectively. The galvanic corrosion may refer to a cell reaction that occurs when conductors having different electrochemical potentials react in an electrolyte solution. In the comparative example of FIG. 3B, an oxidation reaction may occur at a surface of the tungsten plug 335 that is in contact with the solution 340, and a reduction reaction may occur at a surface of the titanium nitride barrier layer 324 that is in contact with the solution 340. As a result, tungsten in the tungsten plug 335 is ionized and discharged into the solution 340, so that the loss of the upper portion of the tungsten plug 335 may occur.

In contrast, in the embodiments of the present disclosure described above with reference to FIGS. 1A, 1B, 2A, and 2B, the metal plug 235 and the metal nitride barrier layer 225 may include the same metal element. Thereby, a difference between electrochemical potentials of the metal plug 235 and the metal nitride barrier layer 225 is reduced, and the galvanic corrosion reaction can be suppressed.

Further, as compared with the above comparative example, in the embodiments of the present disclosure, the metal nitride barrier layer 225 may be formed to have an amorphous phase or a partially crystalline phase. For example, the metal nitride barrier layer 225 has the partially crystalline phase when a percentage of a crystalline portion of the metal nitride barrier layer 225 is in a range from 10% to 90% in volume. By forming the metal nitride barrier layer 225 to have a lower degree of crystallinity than the substantially completely crystalline phase, the resistivity of the metal nitride barrier layer 225 can be higher than that of a metal nitride barrier layer having the substantially completely crystalline phase. Accordingly, since a number of electrons in the metal nitride barrier layer 225 moving to an interface between the solution 340 and the metal nitride barrier layer 225 can be reduced compared with that of electrons moving to an interface between the solution 340 and the metal nitride barrier layer that has the substantially completely crystalline phase, when the reduction reaction of galvanic corrosion occurs, a reaction rate of the galvanic corrosion can be reduced.

In addition, as compared with the above comparative example, in the embodiments of the present disclosure, acid polishing slurry can be applied to the chemical mechanical polishing process, as will be described later. Due to a solution containing the acidic polishing slurry, a nonconductive passivation layer may be formed on a surface of the metal nitride barrier layer 225 and a surface of the metal plug 235 through a chemical reaction. Thereby, the oxidation reaction of the galvanic corrosion on the metal plug 235 can be suppressed when the chemical mechanical polishing process is performed.

Further, as compared with the above comparative example, in the embodiments of the present disclosure, the first and second interconnection pattern layers 125 and 145 disposed under the metal plug 235 may include a conductive material having resistivity lower than that of the metal plug 235.

In the chemical mechanical polishing process, when a resistance value of the lower interconnection pattern layers (e.g., the first and second interconnection pattern layers 125 and 145) is relatively low, an occurrence frequency of the galvanic corrosion can be reduced. Although embodiments of the present disclosure are not limited by a specific theory, one of the reasons why the occurrence frequency of the galvanic corrosion is reduced can be explained as follows.

As described above, the galvanic corrosion may correspond to a cell reaction in which electrons moves between the metal plug 235 and the metal nitride barrier layer 225. Therefore, if a conduction path of electrons from the metal plug 235 to the substrate 101 has a relatively low electrical resistance (i.e., a relatively high electrical conductance), at least a portion of the electrons, which could have participated in the galvanic corrosion in the absence of the conduction path, can be discharged through the conduction path to the grounded substrate 101.

As illustrated in FIG. 3B, in the semiconductor device 30 of the comparative example, an electrical path can be formed from the tungsten plug 335 to the substrate 101 via a second interconnection pattern layer 304, a second contact plug 303, a first interconnection pattern layer 302, and a first contact plug 301.

The electrical conductance of the electrical path through which the electrons originating from the tungsten plug 335 reach the substrate 101 depends on a length and an area of the first and second interconnection pattern layers 302 and 304 as well as conductivity of the first and second interconnection pattern layers 302 and 304. Specifically, the electrical conductance of the electrical path may decrease as a length of the first interconnection pattern layer 302 in the Z-axis direction, a length of the second interconnection pattern layer 304 in the Z-axis direction, or both increase and as a cross-sectional area of the first interconnection pattern layer 302 on the X-Y plane, a cross-sectional area of the second interconnection pattern layer 304 on the X-Y plane, or both decrease. As one example, the electrical conductance of the electrical path from the tungsten plug 335 to the substrate 101 may decrease as the resistance of the first and second interconnection pattern layers 302 and 304 increases. For example, the electrical conductance of the electrical path from the tungsten plug 335 to the substrate 101 decreases by increasing the resistivity of the first and second interconnection pattern layers 302 and 304. As another example, the electrical conductance of the electrical path from the tungsten plug 335 to the substrate 101 may decrease as the number of interconnection pattern layers disposed between the tungsten plug 335 and the substrate 101 increases. As a result, electrons of relatively high density can participate in the reduction reaction of galvanic corrosion in the comparative example shown in FIG. 3B. In contrast, in the embodiments of the present disclosure, as compared with the above comparative example, the density of electrons discharged from the metal plug 235 to the substrate 101 can be increased due to the decreased resistance of the interconnection pattern layers 125 and 145, for example, by making the resistivity of the interconnection pattern layers 125 and 145 smaller than that of the first and second interconnection pattern layers 302 and 304 in the comparative example. As a result, the galvanic corrosion can be substantially suppressed.

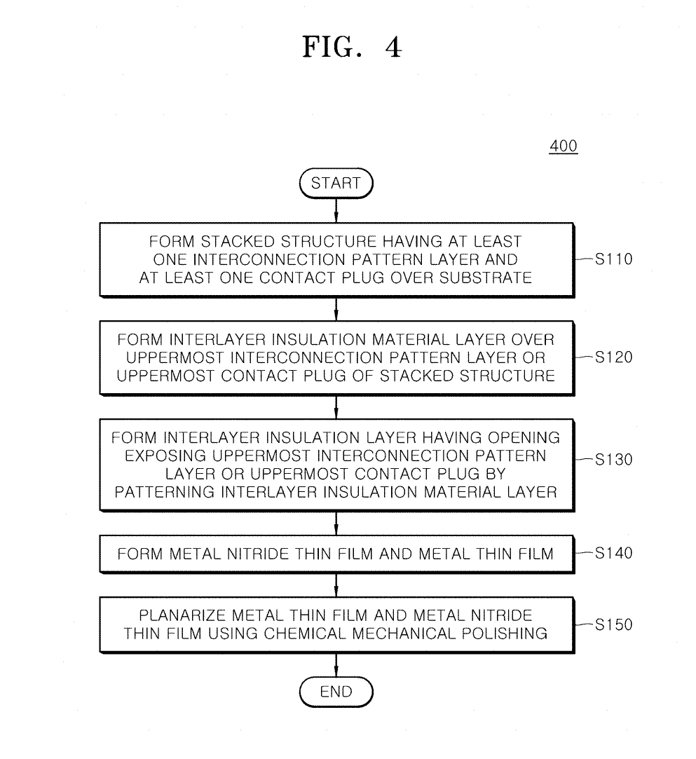

FIG. 4 is a flow chart schematically illustrating a method 400 of manufacturing a semiconductor device having a multilayer interconnection structure according to an embodiment of the present disclosure.

Referring to FIG. 4, at step S110, a stacked structure having at least one interconnection pattern layer and at least one contact plug may be formed over a substrate. The at least one interconnection pattern layer includes an uppermost interconnection layer, and the at least one contact plug includes an uppermost contact plug.

At step S120, an interlayer insulation material layer may be formed over the uppermost interconnection pattern layer or over the uppermost contact plug of the stacked structure.

At step S130, the interlayer insulation material layer may be patterned to form an interlayer insulation layer exposing the uppermost interconnection pattern layer or the uppermost contact plug. In an embodiment, the interlayer insulation layer includes one or more openings that expose a portion of the uppermost interconnection pattern layer or a portion of the uppermost contact plug.

At step S140, a metal nitride thin film may be formed over the interlayer insulation layer, and a metal thin film may be formed over the metal nitride thin film. In an embodiment, a portion of the metal nitride thin film may be disposed inside the one or more openings of the interlayer insulation layer. More specifically, the metal nitride thin film may be formed on a side surface and a bottom surface of one of the openings. The metal nitride thin film may function as a diffusion barrier layer. The metal thin film may be formed on the metal nitride thin film. The metal thin film may fill the remaining portions of the one or more openings in which the metal nitride thin film is formed.

At step S150, the metal thin film and the metal nitride thin film may be planarized using chemical mechanical polishing. The chemical mechanical polishing may be performed using acidic polishing slurry. For example, the polishing slurry may have a potential of Hydrogen (PH) in a range from pH 2 to pH 5.

In an embodiment, a conductive plug electrically connected to the uppermost interconnection pattern layer or to the uppermost contact plug is formed by planarizing the metal thin film and the metal nitride thin film. The conductive plug may be electrically connected to the substrate via the at least one interconnection pattern layer and the at least one contact plug.

By performing the above described processes, the semiconductor device having a multilayer interconnection structure can be manufactured.

In an embodiment, the at least one interconnection pattern layer formed at step S110 may include a conductive material having resistivity lower than that of the metal thin film. In addition, the at least one contact plug formed at step S110 may include a conductive material having resistivity lower than that of the metal thin film.

In an embodiment, the metal thin film and the metal nitride thin film formed at step S140 may include the same metal element.

In an embodiment, the metal nitride thin film may be formed at step S140 using a metal organic material as a metal source material. As an example, the metal nitride thin film may be formed by performing a chemical vapor deposition method or an atomic layer deposition method, which use the metal organic material as the metal source material. As a result, the metal nitride thin film may have an amorphous or partially crystalline phase. Thus, the metal nitride thin film may have a lower degree of crystallinity compared with a substantially completely crystalline metal nitride thin film.

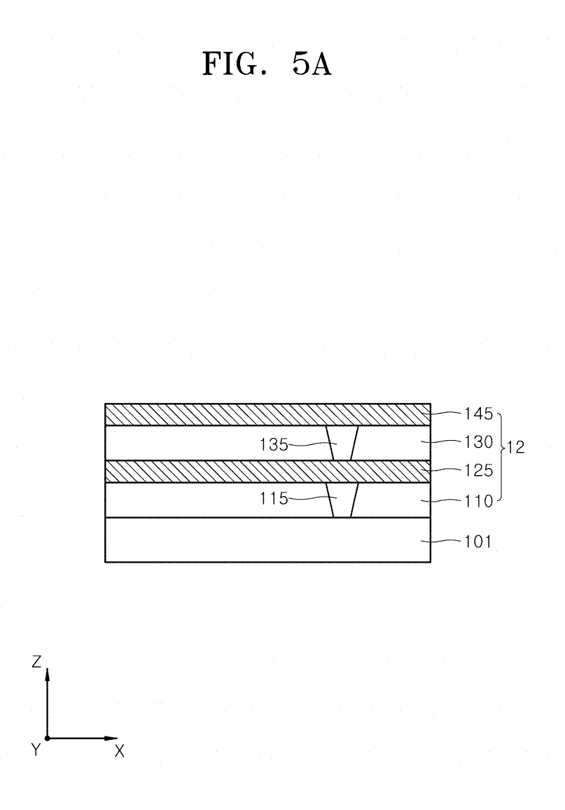

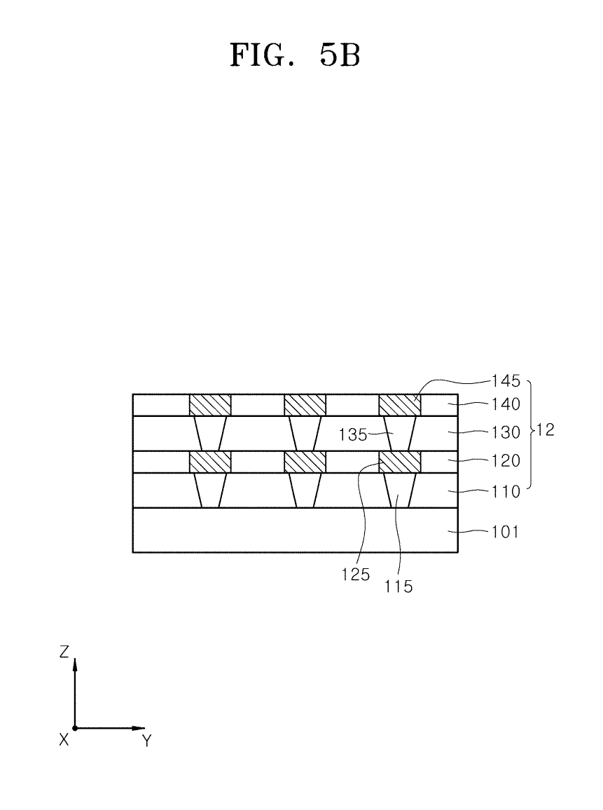

FIGS. 5A to 9B are cross-sectional views, which illustrate a method of manufacturing a semiconductor device having a multilayer interconnection structure according to an embodiment of the present disclosure. Specifically, FIGS. 5A, 6A, 7A, 8A, and 9A are cross-sectional views of a stacked structure on an X-Z plane, and FIGS. 5B, 6B, 7B, 8B, and 9B are cross-sectional views of the stacked structure on a Y-Z plane.

Referring to FIGS. 5A and 5B, a stacked structure 12 may be formed on a substrate 101. The substrate 101 may, for example, be a semiconductor substrate. Specifically, the substrate 101 may, for example, be a silicon (Si) substrate, a gallium arsenide (GaAs) substrate, an indium phosphide (InP) substrate, a germanium (Ge) substrate, a silicon germanium (SiGe) substrate, or a silicon-on-insulator (SOI) substrate. The substrate 101 may be doped with n-type or p-type impurities. The substrate 101 may have one or more wells, each of which is at least partially doped with n-type or p-type impurities.

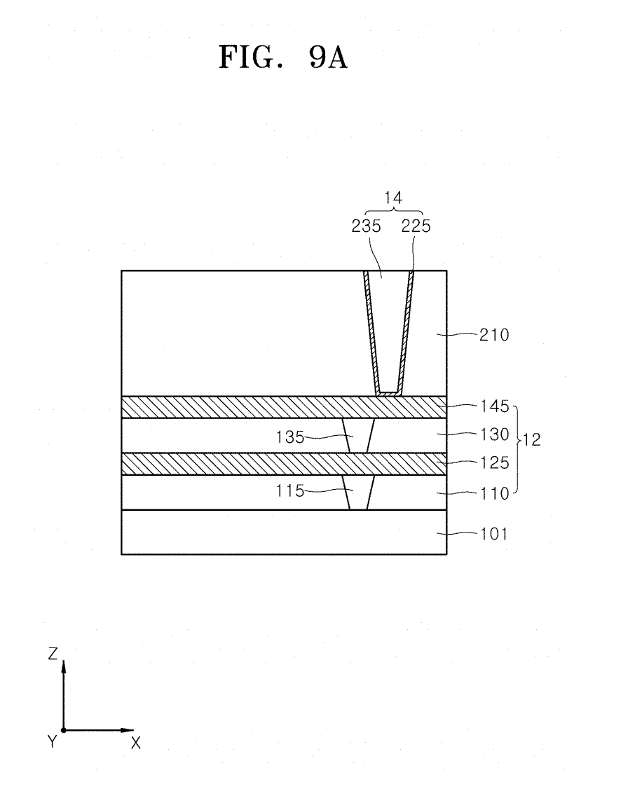

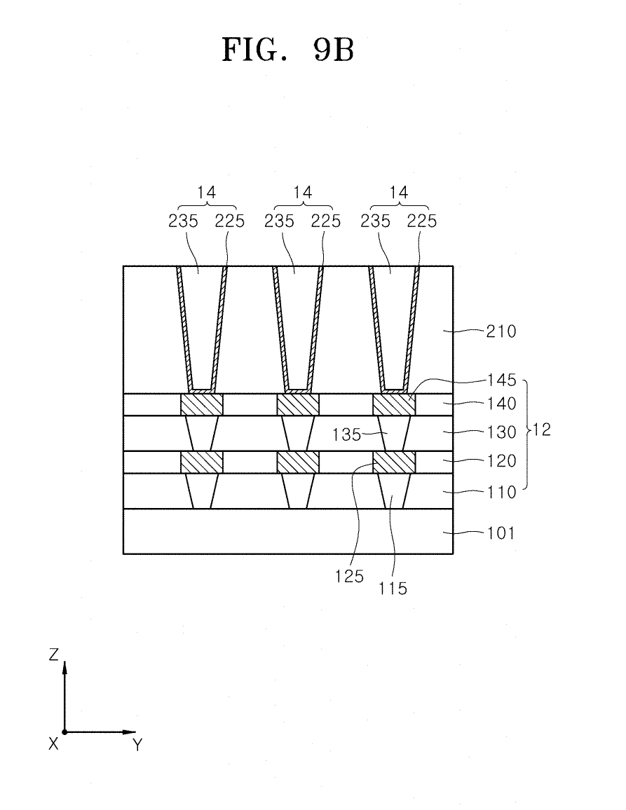

The stacked structure 12 may be formed as follows. Firstly, a first insulation layer 110 may be formed on the substrate 101. The first insulation layer 110 may, for example, include an oxide having a low dielectric constant such as silicon oxide. Next, the first insulation layer 110 may be patterned to form one or more openings exposing corresponding portions of the substrate 101. Then, each of the openings may be filled with a conductive material to form a first contact plug 115. The first contact plug 115 may, for example, include a metal or a metal nitride. The first contact plug 115 may, for example, include tungsten (W), tungsten nitride, titanium nitride, or the like. In some embodiments, the first contact plug 115 may include a conductive material having resistivity lower than that of a metal plug 235 shown in FIGS. 9A and 9B. As an example, when the metal plug 235 includes tungsten (W), the first contact plug 115 may include copper (Cu), cobalt (Co), or platinum (Pt).

In some embodiments, before filling the openings with a conductive material, a barrier material layer (not shown) may be formed in each of the openings to contact a portion of the first insulation layer 110 and a portion of the substrate 101. The barrier material layer may, for example, include tungsten nitride or titanium nitride. The barrier material layer may be disposed between the first contact plug 115 and the portion of the first insulation layer 110 and between the first contact plug 115 and the portion of the substrate 101.

Subsequently, a second insulation layer 120 and a first interconnection pattern layer 125 may be formed on the first insulation layer 110 and the first contact plug 115. More specifically, after forming the second insulation layer 120 on the first insulation layer 110 and the first contact plug 115, the second insulation layer 120 may be patterned to form one or more openings, a corresponding one of the openings exposing the first contact plug 115. Next, the openings may be filled with a conductive material to form the first interconnection pattern layer 125.

In an embodiment, the first interconnection pattern layer 125 may include a conductive material having lower resistivity than that of the metal plug 235 shown in FIGS. 9A and 9B. As an example, when the metal plug 235 includes tungsten, the first interconnection pattern layer 125 may include copper (Cu), cobalt (Co), or platinum (Pt). Substantially the same steps as the above-described steps of forming the first insulation layer 110, the first contact plug 115, the first interconnection pattern layer 125, and the second insulation layer 120 may be sequentially performed to form a third insulation layer 130, a second contact plug 135, a second interconnection pattern layer 145, and a fourth insulation layer 140. Thus, the stacked structure 12 can be formed. Here, the first contact plug 115 may connect the substrate 101 to the first interconnection pattern layer 125. The second contact plug 135 may connect the first interconnection pattern layer 125 to the second interconnection pattern layer 145 in a vertical direction (e.g., the Z-axis direction in FIGS. 5A and 5B).

Meanwhile, in the embodiment of FIGS. 5A and 5B, the stacked structure 12 includes the first and second interconnection pattern layers 125 and 145 and the first and second contact plugs 115 and 135, but embodiments are not limited thereto. In some embodiments, the stacked structure 12 may include at least one interconnection pattern layer and at least one contact plug.

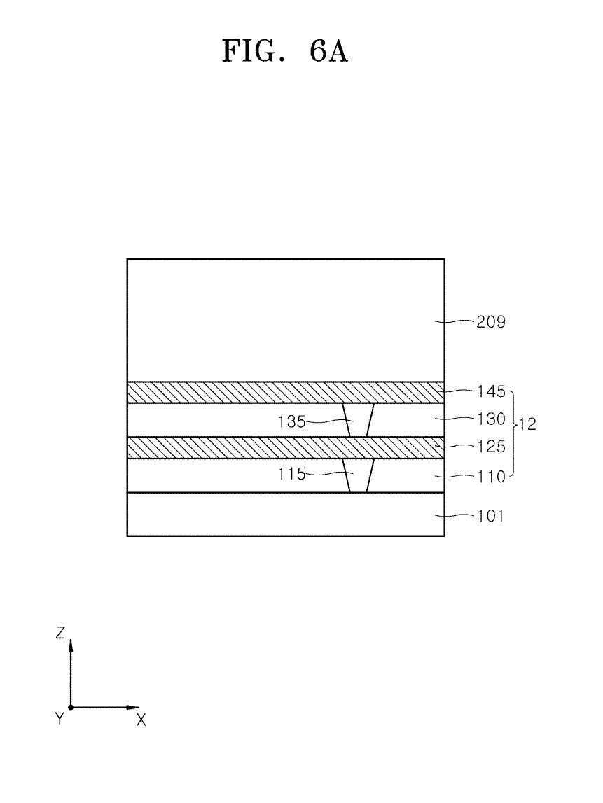

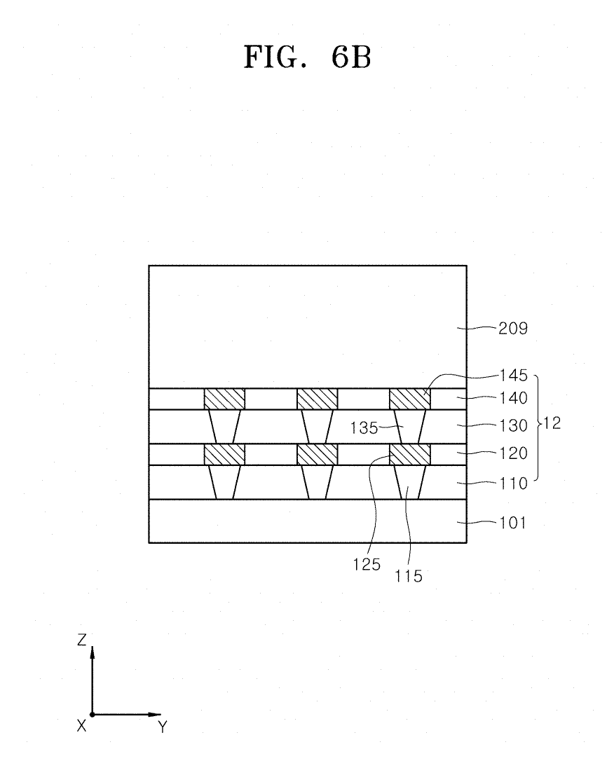

Referring to FIGS. 6A and 6B, an interlayer insulation material layer 209 may be formed on the fourth insulation layer 140 and the second interconnection pattern layer 145 of the stacked structure 12. The interlayer insulation material layer 209 may, for example, include an oxide, a nitride, or an oxynitride. In an embodiment, a thickness of the interlayer insulation material layer 209 may be greater than that of each of the first, second, third, and fourth insulation layers 110, 120, 130, and 140.

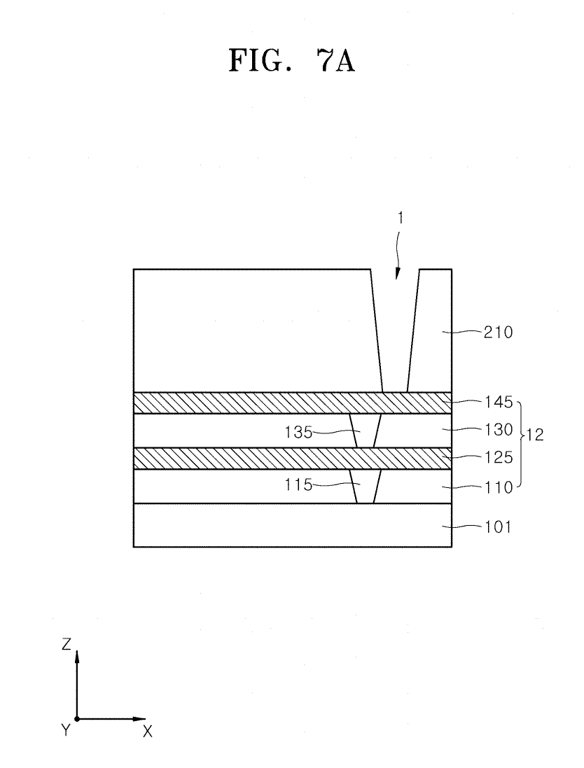

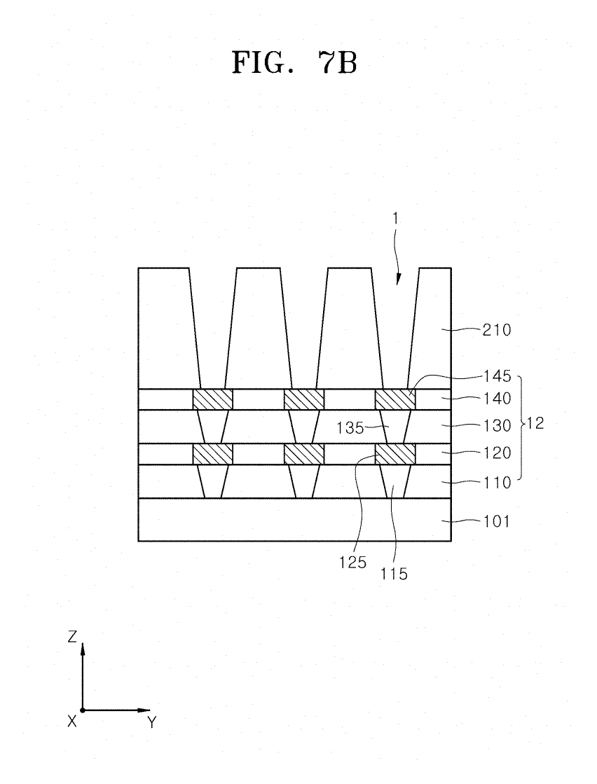

Referring to FIGS. 7A and 7B, the interlayer insulation layer 210 may be formed by patterning the interlayer insulation material layer 209 in FIGS. 6A and 6B. As a result, a contact pattern having one or more openings 1 that expose portions of the second interconnection pattern layer 145 may be formed. The contact pattern may be formed by performing anisotropic etching on the interlayer insulation material layer 209.

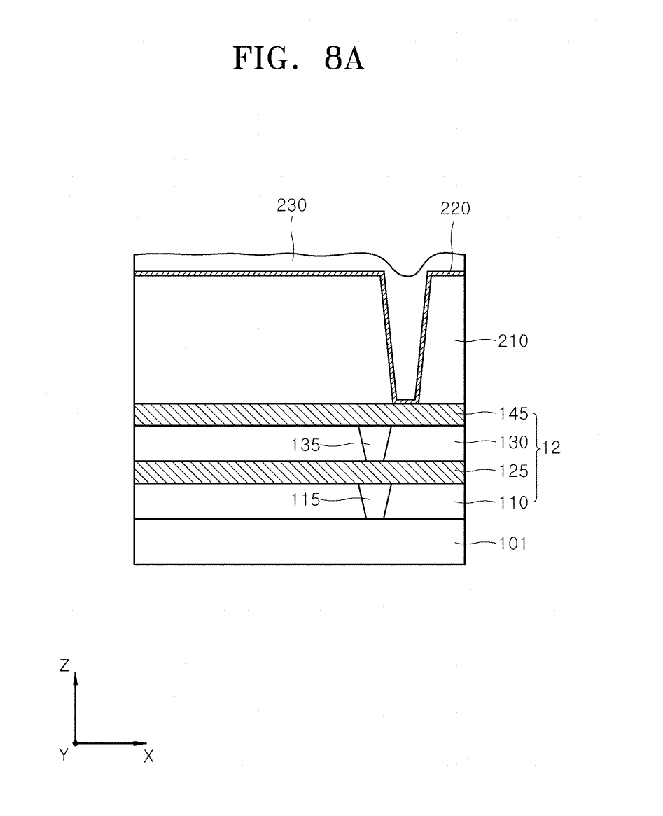

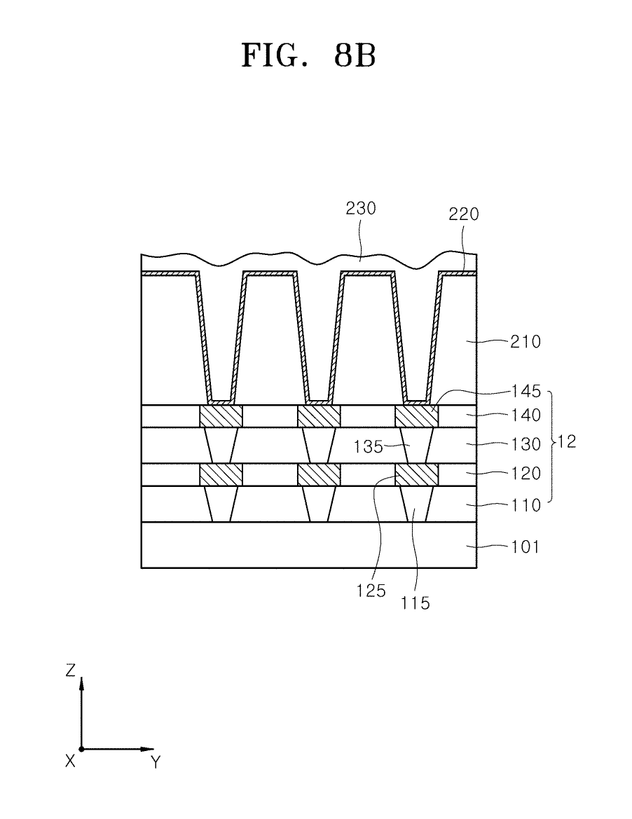

Referring to FIGS. 8A and 8B, a metal nitride thin film 220 may be formed over the substrate 101 along a profile of a resulting structure of FIGS. 7A and 7B, such that the metal nitride thin film 220 may also be formed on an upper surface of the interlayer insulation layer 210. The metal nitride thin film 220 may be formed on a side surface and a bottom of the contact pattern. The metal nitride thin film 220 may, for example, include tungsten nitride or titanium nitride. The metal nitride thin film 220 may function as a diffusion barrier layer.

In an embodiment, the metal nitride thin film 220 may be formed by performing a chemical vapor deposition method or an atomic layer deposition method using a metal organic material as a source material. In this case, the metal nitride thin film 220 may be in an amorphous phase. In another embodiment, the metal nitride thin film 220 may be in a crystalline phase when the metal nitride thin film 220 is formed by performing a sputtering method or a chemical vapor deposition method.

Next, a metal thin film 230 may be formed on the metal nitride thin film 220. The metal thin film 230 may, for example, be formed by performing a sputtering method, an atomic layer deposition method, a chemical vapor deposition method, or the like.

In an embodiment, the metal thin film 230 and the metal nitride thin film 220 may include the same metal element. As an example, the metal thin film 230 may include tungsten (W) and the metal nitride thin film 220 may include tungsten nitride.

In another embodiment, the metal thin film 230 and the metal nitride thin film 220 may include different metal elements. For example, the metal thin film 230 may include tungsten, and the metal nitride thin film 220 may include an amorphous titanium nitride. Here, the metal nitride thin film 220 may be formed by using a metal organic material as a metal source material. The metal nitride thin film 220 may include carbon (C) as an impurity.

Referring to FIGS. 9A and 9B, the metal thin film 230 and the metal nitride thin film 220 of FIGS. 8A and 8B may be planarized by a chemical mechanical polishing process using acidic polishing slurry. The metal thin film 230 and the metal nitride thin film 220 may be planarized until upper surfaces of the metal thin film 230, the metal nitride thin film 220, and the interlayer insulation layer 210 are positioned on substantially the same plane. As a result, a conductive plug 14 including a metal nitride barrier layer 225 and a metal plug 235 is formed in the openings 1 of the contact pattern. The polishing slurry may, for example, have a hydrogen ion concentration in a range from pH 2 to pH 5.

The chemical mechanical polishing process may be performed using a solution containing acidic slurry. A nonconductive passivation layer may be formed on surfaces of the metal nitride barrier layer 225 and the metal plug 235 by reactions of the metal nitride barrier layer 225 and the metal plug 235 with the solution containing the acidic polishing slurry. Thus, a galvanic corrosion reaction can be substantially suppressed, and the metal of the metal plug 235 can be substantially inhibited from being ionized and discharged into the solution.

In an embodiment, the metal nitride thin film 220 in FIGS. 8A and 8B may have an amorphous phase. In this case, the metal nitride thin film 220 can have higher resistivity than a metal nitride thin film having a crystalline phase, so that conductivity of the metal nitride thin film 220 can be decreased compared with the metal nitride thin film having the crystalline phase. Accordingly, when the chemical mechanical polishing process is performed on the metal thin film 230 and metal nitride thin film 220, a reduction reaction rate of galvanic corrosion at an interface between the metal nitride thin film 220 and the solution containing the acidic polishing slurry can be decreased.

By performing the above-described processes, a semiconductor device having substantially the same configuration as that of the semiconductor device 10 described above with reference to FIGS. 1A and 1B can be manufactured.

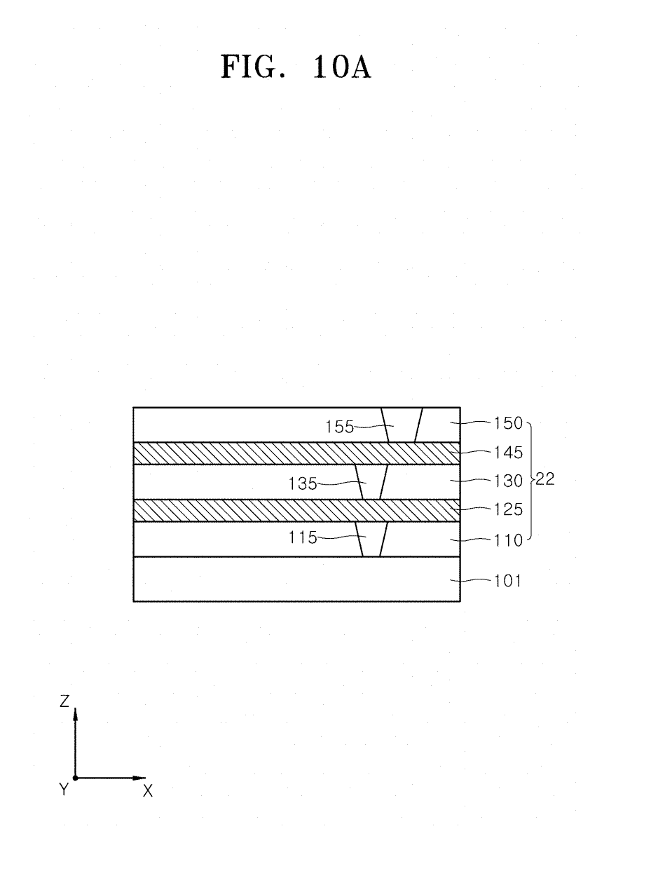

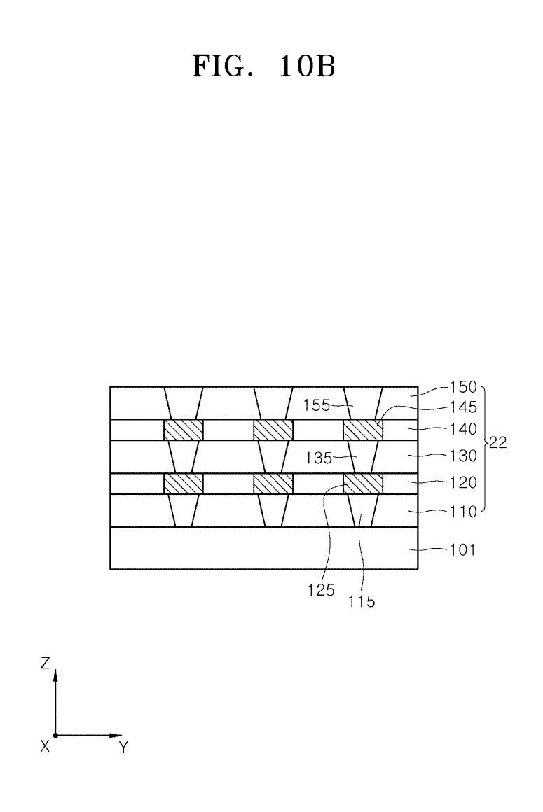

FIGS. 10A to 12B are cross-sectional views illustrating a method of manufacturing a semiconductor device having a multilayer interconnection structure according to another embodiment of the present disclosure. Specifically, FIGS. 10A, 11A, and 12A are cross-sectional views of a stacked structure on an X-Z plane, and FIGS. 10B, 11B, 12B are cross-sectional views of the stacked structure on a Y-Z plane.

Referring to FIGS. 10A and 10B, a stacked structure 22 may be formed on a substrate 101. The stacked structure 22 may additionally have a fifth insulation layer 150 including a third contact plug 155, as compared to the stacked structure 12 described above with reference to FIGS. 5A and 5B. The third contact plug 155 is disposed on the second interconnection pattern layer 145. A process of forming the third contact plug 155 and the fifth insulation layer 150 may be substantially the same as the process of forming the second contact plug 135 and the third insulation layer 130.

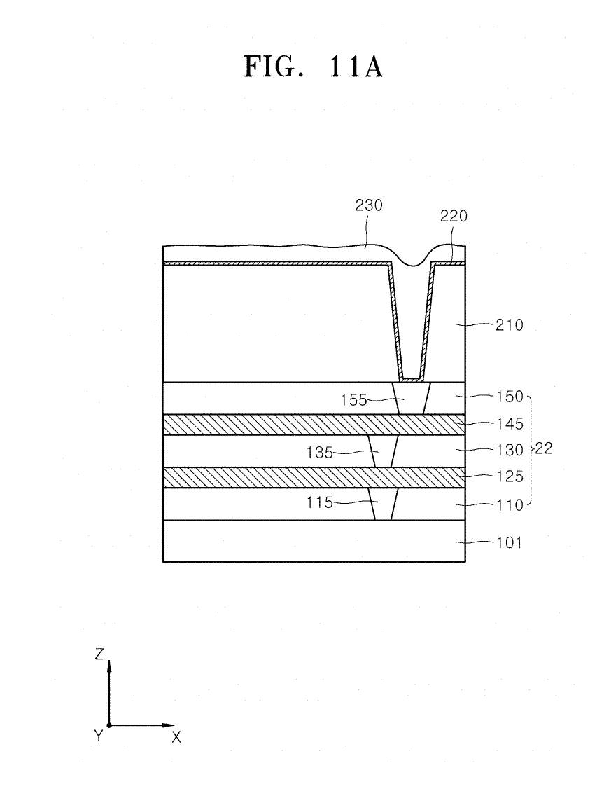

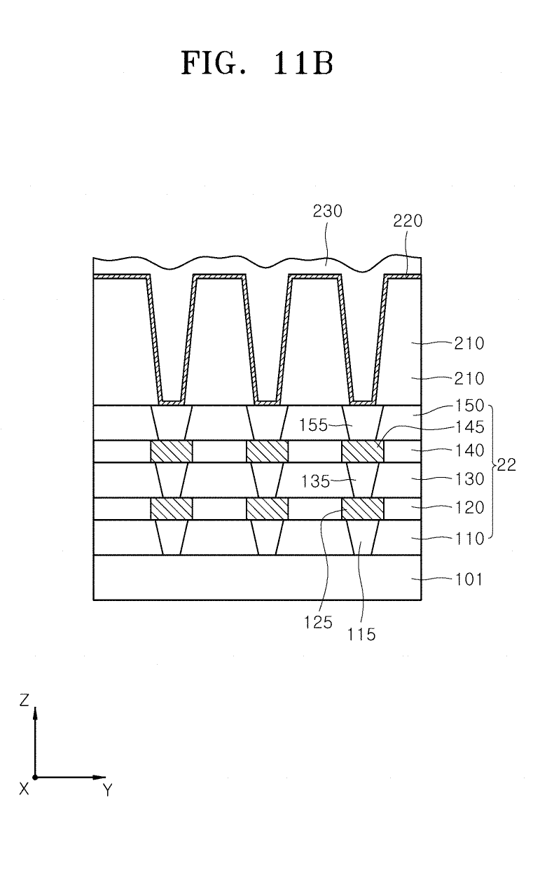

Referring to FIGS. 11A and 11B, the processes described above with reference to FIGS. 6A to 8A and 6B to 8B may be sequentially performed to form an interlayer insulation layer 210, a metal thin film 230, and a metal nitride thin film 220 over the third contact plug 155 and the fifth insulation layer 150.

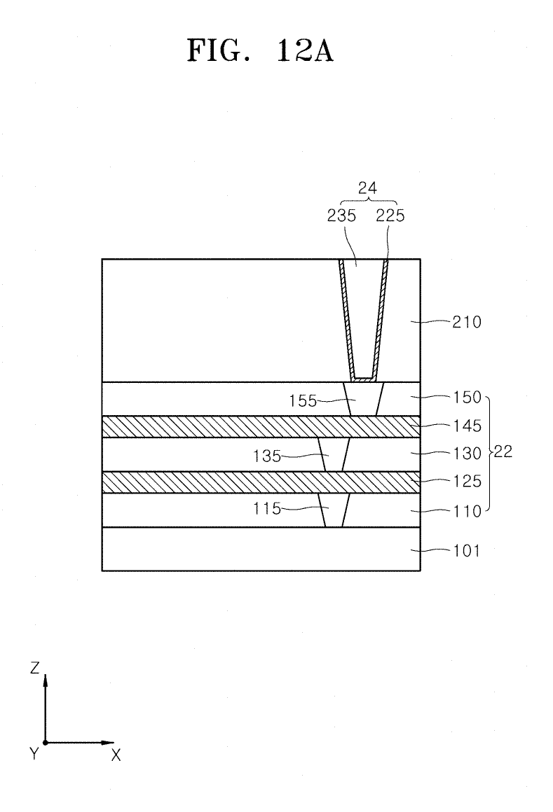

Referring to FIGS. 12A and 12B, a chemical mechanical polishing process using acidic polishing slurry may be performed on the metal thin film 230 and the metal nitride thin film 220 of FIGS. 11A and 11B. As a result, a conductive plug 24 including a metal plug 235 and a metal nitride barrier layer 225 may be formed by performing the chemical mechanical polishing process on the metal thin film 230 and the metal nitride thin film 220.

By performing the above-described processes, a semiconductor device having substantially the same configuration as that of the semiconductor device 20 described above with reference to FIGS. 2A and 2B can be manufactured.

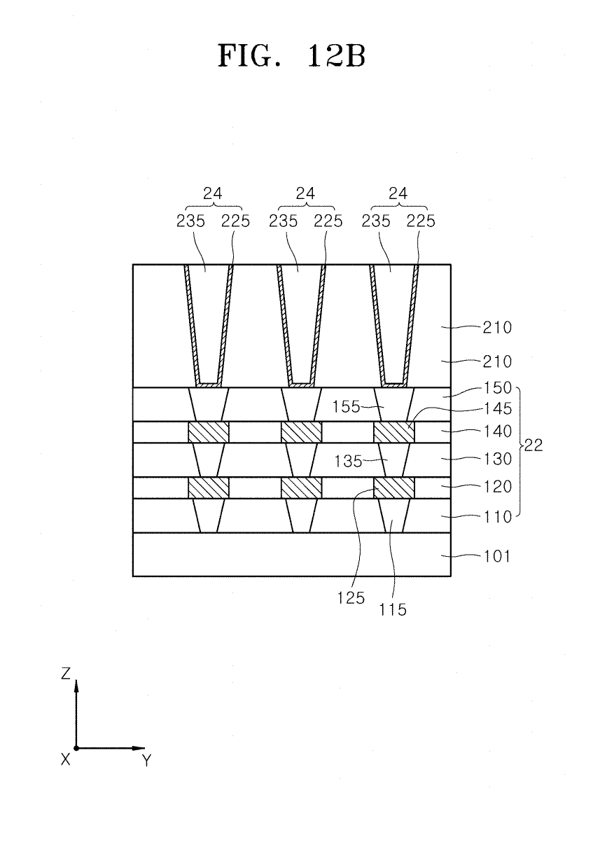

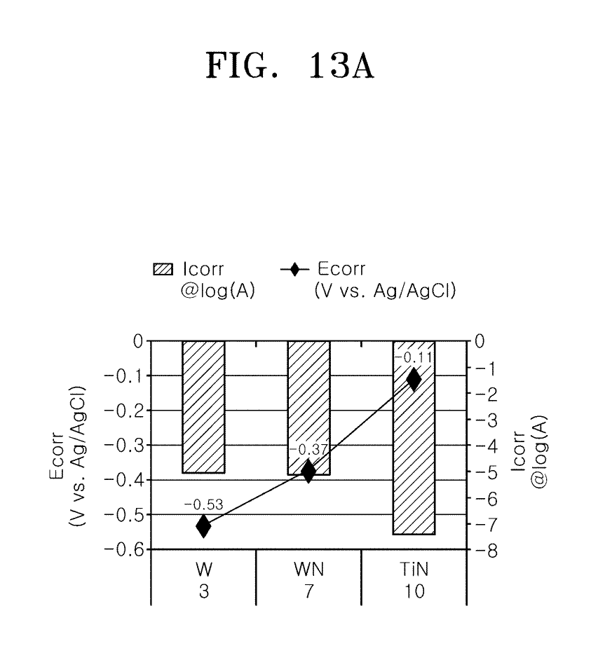

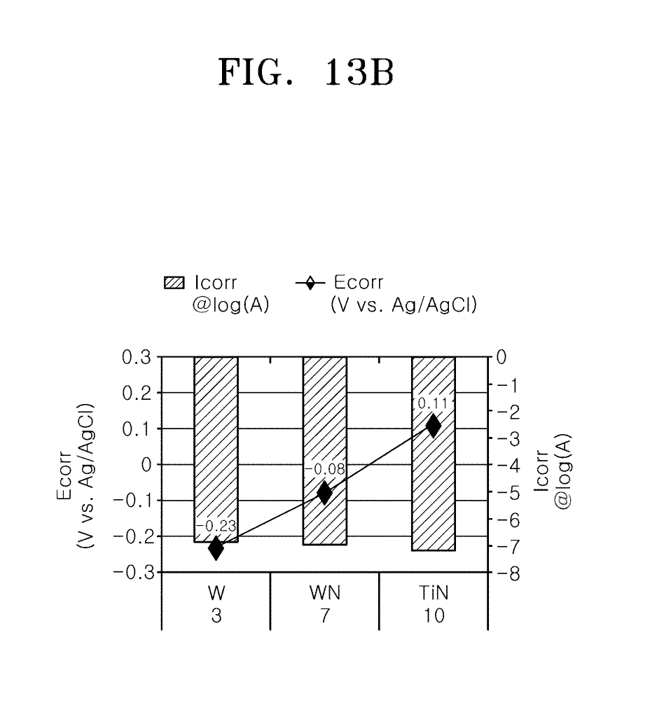

FIGS. 13A and 13B are graphs each illustrating a potential and a current density of an electrode reaction for a material under a chemical mechanical polishing process condition according to an embodiment of the present disclosure. Specifically, FIG. 13A illustrates a potential and a current density of a first electrode reaction using basic polishing slurry according to a comparative example, and FIG. 13B illustrates a potential and a current density of a second electrode reaction using acidic polishing slurry according to an embodiment. The basic polishing slurry may have a hydrogen ion concentration of pH 10.9, and the acidic polishing slurry may have a hydrogen ion concentration of pH 4.

FIGS. 13A and 13B illustrate results of measuring a potential (Ecorr) and a current density (Icorr) of an electrode reaction of a working electrode with respect to a reference electrode. The working electrode may be a tungsten electrode, a tungsten nitride electrode, and a titanium nitride electrode. The reference electrode may be a silver/silver chloride (Ag/AgCl) electrode. The measurement results respectively indicate an average value of electrode reaction potential and an average value of electrode reaction current density of the tungsten electrode, an average value of electrode reaction potential and an average value of electrode reaction current density of the tungsten nitride electrode, and an average value of electrode reaction potential and an average value of electrode reaction current density of the titanium nitride electrode, which are obtained by repeating a plurality of experiments for the same electrode.

Referring to FIG. 13A, the electrode reaction potential of the tungsten (W) electrode, the electrode reaction potential of the tungsten nitride (WN) electrode, and the electrode reaction potential of the titanium nitride (TiN) electrode are measured to about −0.53 V, about −0.37 V, and about −0.11 V, respectively, with respect to the electrode reaction potential of the silver/silver chloride (Ag/AgCl) reference electrode. The electrode reaction current density of the tungsten (W) electrode, the electrode reaction current density of the tungsten nitride (WN) electrode, and the electrode reaction current density of the titanium nitride (TiN) electrode are measured to about −5 A/cm², about −5 A/cm², and about −7.5 A/cm², respectively, with respect to the electrode reaction current density of the silver/silver chloride (Ag/AgCl) reference electrode.

On the other hand, referring to FIG. 13B, the electrode reaction potential of the tungsten (W) electrode, the electrode reaction potential of the tungsten nitride (WN) electrode, and the electrode reaction potential of the titanium nitride (TiN) electrode are measured to about −0.23 V, about −0.08 V, and about −0.11 V, respectively, with respect to the electrode reaction potential of the silver/silver chloride (Ag/AgCl) reference electrode. Also, the electrode reaction current density of the tungsten (W) electrode, the electrode reaction current density of the tungsten nitride (WN) electrode, and the electrode reaction current density of the titanium nitride (TiN) electrode are measured to about −7 A/cm², about −7 A/cm², and about −7 A/cm², respectively, with respect to the electrode reaction current density of the silver/silver chloride (Ag/AgCl) reference electrode.

According to the measurement results illustrated in FIG. 13A when the basic polishing slurry is used and a tungsten plug corresponding to the tungsten electrode and a tungsten nitride barrier layer corresponding to the tungsten nitride electrode are applied, a driving voltage of galvanic corrosion corresponding to a difference in electrode reaction potentials between the tungsten plug and the tungsten nitride barrier layer can be about 0.16 V. In addition, when the tungsten plug and a titanium nitride barrier layer corresponding to the titanium nitride electrode are applied, a driving voltage of galvanic corrosion can be about 0.42 V. That is, it can be observed that the driving voltage when the tungsten plug and the tungsten nitride barrier layer are applied is relatively low compared with that when the tungsten plug and the titanium nitride barrier layer are applied.

According to the measurement results of FIG. 13B when the acidic polishing slurry is used and a tungsten plug corresponding to the tungsten electrode and a tungsten nitride barrier layer corresponding to the tungsten nitride electrode are applied, a driving voltage of galvanic corrosion can be about 0.15 V. In addition, when the tungsten plug and a titanium nitride barrier layer corresponding to the titanium nitride electrode are applied, a driving voltage of galvanic corrosion can be about 0.34 V. That is, it can be observed that the driving voltage when the tungsten plug and the tungsten nitride barrier layer are applied is relatively low compared with that when the tungsten plug and the titanium nitride barrier layer are applied.

Meanwhile, comparing FIGS. 13A and 13B, it can be observed that, the driving voltage of a pair of a metal plug and a metal nitride barrier layer for generating galvanic corrosion when the acidic polishing slurry is used is lower than the driving voltage of the pair when the basic polishing slurry is used. Also, referring to FIG. 13B, the current densities of galvanic corrosion of tungsten (W), tungsten nitride (WN), and titanium nitride (TiN) are measured at substantially the same level in respective electrode reactions using a silver-silver chloride (Ag/AgCl) reference electrode. This may indicate that the acidic polishing slurry forms a nonconductive passivation layer on surfaces of tungsten (W), tungsten nitride (WN), and titanium nitride (TiN) to suppress the galvanic corrosion reaction.

Hereinafter, experimental examples according to embodiments of the present disclosure will be described.

### Experimental Example

Specimens of semiconductor devices each having a stacked structure disposed on a substrate were prepared as shown in Table 1 below. The stacked structure included five interconnection pattern layers and five or more contact plugs. A lowermost contact plug among the contact plugs was configured to be in contact with the substrate, and the five interconnection pattern layers were configured to be electrically connected to each other by the contact plugs.

Next, an interlayer insulation layer having a contact pattern was formed on the stacked structure. Then, a metal thin film and a metal nitride thin film were formed in a contact pattern for each of a comparative example Comparative Example, a first embodiment Example 1, a second embodiment Example 2, and a third embodiment Example 3 under corresponding process conditions of Table 1. Subsequently, a chemical mechanical polishing (CMP) process is performed on the metal thin film and the metal nitride thin film to form a metal plug and a metal nitride barrier layer. The metal nitride thin film was deposited by a chemical vapor deposition (CVD) method at 480° C. using TiCl₄ and ammonia, in Comparative Example. In Example 2, the metal nitride thin film was deposited by a metal-organic chemical vapor deposition (MOCVD) method at 350° C. using a metal organic source containing carbon and ammonia.

TABLE 1

| | | | | | | | | | CMP |
|---|---|---|---|---|---|---|---|---|---|
| | | Contact | | | | | | | process |
| | Interconnection | plug | Metal nitride thin film | | | Metal thin film | | | condition |
| | material | material | material | process | Thickness(Å) | material | Process | Thickness(Å) | Slurry pH |
| Comparative | W | W | TiN | CVD | 55 | W | CVD | 1000 | 10.9 |
| Example | | | | | | | | | |
| Example 1 | W | W | WN | CVD | 35 | W | CVD | 1000 | 10.9 |
| Example 2 | Cu | Cu | TiN | MOCVD | 75 | W | CVD | 500 | 4 |
| Example 3 | Cu | Cu | WN | CVD | 35 | W | CVD | 1000 | 4 |

Review

The respective metal plugs formed in the comparative example Comparative Example and the first to third embodiments Examples 1 to 3 were observed, and the results are shown in Table 2.

TABLE 2

| | Loss of metal plug |
|---|---|
| Comparative Example | Loss |
| Example 1 | No Loss |
| Example 2 | No Loss |
| Example 3 | No Loss |

In Comparative Example, the interconnection pattern layers and the contact plugs of the stacked structure were formed of tungsten, and the metal nitride thin film and the metal thin film were formed of titanium nitride and tungsten, respectively, and basic slurry was applied in the CMP process. At this time, the metal nitride thin film was formed using TiCl₄ and ammonia as a source. In this case, a portion of the metal plug was lost.

In Example 1, as compared with Comparative Example, the metal nitride thin film and the metal thin film were formed of tungsten nitride and tungsten, respectively. That is, the same metal element, e.g., tungsten, was used in the metal nitride thin film and the metal thin film. In this case, the metal plug was not lost.

In Example 2, as compared with Comparative Example, the interconnection pattern layers and the contact plugs of the stacked structure were formed of copper, and thus the interconnection pattern layers and the contact plugs have lower resistivity than the metal plug. In addition, the metal nitride thin film was formed of TiN by a MOCVD method, and thus the metal nitride barrier layer has an amorphous structure. Moreover, acidic slurry was applied in the CMP process, and thus a passivation layer may be formed on top surfaces of the metal plug and the metal nitride barrier layer. In this case, the metal plug was not lost.

In Example 3, as compared with Comparative Example, the interconnection pattern layers and the contact plugs of the stacked structure were formed of copper, and thus the interconnection pattern layers and the contact plugs have lower resistivity than the metal plug. In addition, the metal nitride thin film and the metal thin film were formed of tungsten nitride and tungsten, respectively, and thus the metal plug and the nitride barrier layer include the same metal element, i.e., tungsten. Moreover, acidic slurry was applied in the CMP process, and thus a passivation layer may be formed on surfaces of the metal plug and the metal nitride barrier layer. In this case, the metal plug was not lost.

According to the above-described embodiments of the present disclosure, a conductive plug including a metal nitride barrier film and a metal plug can be structurally and reliably formed on a stacked structure including at least one interconnection pattern layer and at least one contact plug. The conductive plug can be formed using a new thin film stacked structure and under new chemical mechanical polishing process conditions.

In the thin film stacked structure, an interconnection pattern layer may include a conductive material having resistivity lower than that of the metal thin film. In addition, the metal thin film and the metal nitride thin film may include the same metal element. The metal nitride thin film may be formed to have an amorphous phase. Further, in the chemical mechanical polishing process conditions, the chemical mechanical polishing for the metal nitride thin film and the metal thin film to respectively form the metal nitride barrier film and the metal plug included in the conductive plug can be performed by applying acidic polishing slurry.

As a result, it is possible to provide a semiconductor device having a conductive plug, which is structurally stable, on at least one interconnection pattern layer.

The above-described embodiments of the present disclosure have been disclosed for illustrative purposes. Those of ordinary skill in the art will appreciate that various modifications, additions, and substitutions are possible.

What is claimed is:

1. A method of manufacturing a semiconductor device having a multilayer interconnection structure, the method comprising:
forming a stacked structure including at least one interconnection pattern layer and at least one contact plug over a substrate, the at least one interconnection pattern layer including an uppermost interconnection layer, and the at least one contact plug including an uppermost contact plug;
forming an interlayer insulation material layer over the uppermost interconnection pattern layer or the uppermost contact plug of the stacked structure;
patterning the interlayer insulation material layer to form an interlayer insulation layer including one or more openings, the one or more openings exposing the uppermost interconnection pattern layer or the uppermost contact plug;
forming a metal nitride thin film along a surface of a resulting structure including the one or more openings of the interlayer insulation layer;
forming a metal thin film over the metal nitride thin film by filling at least the remaining portions of the one or more openings after the metal nitride thin film is formed; and
planarizing the metal thin film and the metal nitride thin film using chemical mechanical polishing,
wherein the metal thin film and the metal nitride thin film comprise the same metal element, and the at least one interconnection pattern layer comprises a conductive material having resistivity lower than that of the metal thin film.

2. The method of claim 1, wherein the metal thin film comprises tungsten, and the metal nitride thin film comprises tungsten nitride.

3. The method of claim 1, wherein the metal thin film comprises tungsten, and the at least one interconnection pattern layer comprises any one selected from copper (Cu), cobalt (Co), and platinum (Pt).

4. The method of claim 1, wherein when the at least one contact plug further includes a lowermost contact plug, the lowermost contact plug connects the interconnection pattern layer to the substrate, and
wherein when the at least one contact plug further includes an intermediate contact plug, the intermediate contact plug connects adjacent interconnection pattern layers to each other, the adjacent interconnection pattern layers are disposed in a direction perpendicular to a main surface of the substrate.

5. The method of claim 1, wherein planarizing the metal thin film and the metal nitride thin film comprises:
forming a conductive plug electrically connected to the uppermost interconnection pattern layer or the uppermost contact plug by planarizing the metal thin film and the metal nitride thin film, the conductive plug including the planarized metal thin film and the planarized metal nitride thin film,
wherein the conductive plug is electrically connected to the substrate via the at least one interconnection pattern layer and the at least one contact plug.

6. The method of claim 1, wherein slurry used for the chemical mechanical polishing has a potential of Hydrogen (pH) less than 7.

7. A method of manufacturing a semiconductor device having a multilayer interconnection structure, the method comprising:
forming a stacked structure including at least one interconnection pattern layer and at least one contact plug over a substrate, the at least one interconnection pattern layer including an uppermost interconnection layer, and the at least one contact plug including an uppermost contact plug;
forming an interlayer insulation material layer over the uppermost interconnection pattern layer or the uppermost contact plug of the stacked structure;
patterning the interlayer insulation material layer to form an interlayer insulation layer including one or more openings, the one or more openings exposing the uppermost interconnection pattern layer or the uppermost contact plug;
forming a metal nitride thin film along a surface of a resulting structure including the one or more openings of the interlayer insulation layer;
forming a metal thin film over the metal nitride thin film by filling at least the remaining portions of the one or more openings after the metal nitride thin film is formed; and
planarizing the metal thin film and the metal nitride thin film using chemical mechanical polishing,
wherein the at least one interconnection pattern layer comprises a conductive material having resistivity lower than that of the metal thin film, and
wherein the metal nitride thin film is formed using a metal organic material as a metal source material.

8. The method of claim 7, wherein forming the metal nitride thin film is performed by a chemical vapor deposition method or an atomic layer deposition method, using the metal organic material and ammonia.

9. The method of claim 7, wherein the metal nitride thin film comprises carbon (C) as an impurity.

10. The method of claim 7, wherein the metal nitride thin film is formed in an amorphous phase or in a partially crystalline phase.

11. The method of claim 7, wherein the metal thin film comprises tungsten, and the metal nitride thin film comprises titanium nitride in an amorphous phase.

12. The method of claim 11, wherein the at least one interconnection pattern layer comprises any one selected from copper (Cu), cobalt (Co), and platinum (Pt).

13. The method of claim 7, wherein planarizing the metal thin film and the metal nitride thin film comprises:
forming a conductive plug electrically connected to the uppermost interconnection pattern layer or the uppermost contact plug by planarizing the metal thin film and the metal nitride thin film, the conductive plug including the planarized metal thin film and the planarized metal nitride thin film,
wherein the conductive plug is electrically connected to the substrate via the at least one interconnection pattern layer and the at least one contact plug.

14. The method of claim 7, wherein slurry used for the chemical mechanical polishing has a potential of Hydrogen (pH) less than 7.

15. A semiconductor device having a multilayer interconnection structure, the semiconductor device comprising:
a stacked structure disposed over a substrate and including at least one interconnection pattern layer and at least one contact plug, the at least one interconnection pattern layer including an uppermost interconnection layer, and the at least one contact plug including an uppermost contact plug;
an interlayer insulation layer disposed over the uppermost interconnection pattern layer or the uppermost contact plug of the stacked structure; and
a conductive plug disposed in the interlayer insulation layer and connected to the uppermost interconnection pattern layer or the uppermost contact plug,
wherein the conductive plug comprises:
a metal nitride barrier layer contacting the interlayer insulation layer and the uppermost interconnection pattern layer or contacting the interlayer insulation layer and the uppermost contact plug; and
a metal plug disposed on the metal nitride barrier layer,
wherein the at least one interconnection pattern layer comprises a conductive material having resistivity lower than that of the metal plug.

16. The semiconductor device of claim 15, wherein the metal plug and the metal nitride barrier layer comprise the same metal element.

17. The semiconductor device of claim 16, wherein the metal plug comprises tungsten, and the metal nitride barrier layer comprises tungsten nitride.

18. The semiconductor device of claim 15, wherein the metal nitride barrier layer comprises titanium nitride having an amorphous phase or a partially crystalline phase.

19. The semiconductor device of claim 15, wherein the metal plug comprises tungsten, and the at least one interconnection pattern layer comprises any one selected from copper (Cu), cobalt (Co), and platinum (Pt).

20. The semiconductor device of claim 15, wherein the metal plug is electrically connected to the substrate via the at least one interconnection pattern layer and the at least one contact plug.
